(19) United States
(12) Patent Application Publication
(10) Pub. No.: US 2026/0255829 A1
(43) Pub. Date: Aug. 27, 2026

(54) DISPLAY APPARATUS, METHOD OF MANUFACTURING THE SAME AND ELECTRONIC DEVICE INCLUDING THE SAME

(71) Applicant: Samsung Display Co., Ltd., Yongin-si (KR)

(72) Inventors: HYUNGGI JUNG, Yongin-si (KR); YOUNGSEOK PARK, Yongin-si (KR); SOON CHANG YEON, Yongin-si (KR)

(73) Assignee: Samsung Display Co., Ltd., Yongin-si (KR)

(21) Appl. No.: 19/421,733

(22) Filed: Dec. 16, 2025

(30) Foreign Application Priority Data
Feb. 24, 2025 (KR) 10-2025-0023521

(51) Int. Cl. H10K 59/131; H10K 59/12; H10K 59/124; H10K 102/00

(52) U.S. Cl. CPC H10K 59/1315; H10K 59/1201; H10K 59/124; H10K 2102/351

(57) ABSTRACT

A display device may include a substrate, a thin-film transistor on the substrate, an interlayer insulating film on the thin-film transistor, and signal wirings on the interlayer insulating film. The signal wirings may be electrically connected to the thin-film transistor. A surface of the interlayer insulating film may include an uneven portion between the signal wirings.

### CROSS-REFERENCE TO RELATED APPLICATION

This application is based on and claims priority under 35 USC § 119 to Korean Patent Application No. 10-2025-0023521, filed on Feb. 24, 2025 in the Korean Intellectual Property Office, the disclosure of which is incorporated by reference herein in its entirety.

### BACKGROUND

### 1. Field

The embodiments in the present disclosure relate to a display device, a method of manufacturing the same, and/or an electronic device including the same.

### 2. Description of the Related Art

Display devices, such as organic light-emitting diode display devices and liquid crystal display devices, may be manufactured on a substrate having a pattern formed thereon. Display devices may include at least one thin-film transistor (TFT), a capacitor for driving, and wiring connecting that at least one TFT and capacitor. A thin-film transistor may have an active layer providing a channel region, a source region, and a drain region, and a gate electrode electrically insulated from the active layer by a gate insulating layer.

As the resolution of the display device increases, the spacing between the wirings connected to the source region, drain region, and gate electrode respectively may narrow and may make the display more susceptible to current leakage.

The above-described information disclosed in the background technology of is provided solely to enhance the understanding of the background of the present disclosure and therefore may include information that does not constitute prior art.

### SUMMARY

Embodiments of the present disclosure provide a display device, a method of manufacturing the same, and/or an electronic device including the same, in which an uneven portion may be disposed on an insulating layer between the wirings respectively connected to a source region, a drain region, and a gate electrode, thereby increasing surface resistance between the wirings, alleviating and/or preventing current leakage, and/or improving reliability.

However, the scope of the present disclosure is not limited thereto.

According to an embodiment of the present disclosure, a display device may include a substrate; a thin-film transistor on the substrate; an interlayer insulating film on the thin-film transistor; and signal wirings on the interlayer insulating film and electrically connected to the thin-film transistor. A surface of the interlayer insulating film may include an uneven portion between the signal wirings.

In some embodiments, the thin-film transistor may include a semiconductor layer, a gate insulating film, and a gate electrode. The semiconductor layer may include a channel region, a source region, and a drain region. The source region and the drain region respectively may be positioned on opposite sides of the channel region. The gate electrode may overlap the channel region. The gate insulating film may be between the gate electrode and the channel region.

In some embodiments, the signal wirings may include a first signal wiring, a second signal wiring, and a third signal wiring. The first signal wiring may be configured to apply a gate signal to the gate electrode. The second signal wiring may be electrically connected to the source region. The third signal wiring may be electrically connected to the drain region. The uneven portion may be between the first signal wiring, the second signal wiring, and the third signal wiring.

In some embodiments, the uneven portion may include at least one concave portion.

In some embodiments, the depth of a concave portion may be 500 Å or more and 1000 Å or less.

In some embodiments, the at least one concave portion may include two or more concave portions. The two or more concave portion may have different depths and/or widths from each other.

In some embodiments, the interlayer insulating film may further include an additional insulating film covering the uneven portion.

In some embodiments, the thickness of the additional insulating film may be 500 Å or more and 1000 Å or less.

In some embodiments, the permittivity of the additional insulating film may be 4 or lower.

According to an embodiment of the present disclosure, a method of manufacturing a display device may include forming a thin-film transistor on a substrate by sequentially forming a semiconductor layer, a gate insulating film, and a gate electrode on the substrate; forming an interlayer insulating film on the thin-film transistor; forming an uneven portion on a surface of the interlayer insulating film; and forming signal wirings electrically connected to the thin-film transistor, the signal wirings being formed on the interlayer insulating film.

In some embodiments, the forming the uneven portion on the surface of the interlayer insulating film may include: forming a photoresist layer by coating a photoresist material on the interlayer insulating film; forming a photoresist pattern on the photoresist layer using a half-tone mask; and patterning the interlayer insulating film using the photoresist pattern as a mask.

In some embodiments, the forming the photoresist pattern may include performing an exposure process and a developing process on the photoresist material.

In some embodiments, the concave portion may be between the signal wirings.

In some embodiments, the method may further include: between the forming the thin-film transistor and the forming the interlayer insulating film, forming a source region in the semiconductor layer and a drain region in the semiconductor layer by the doping an impurity into the semiconductor layer using the gate electrode as a mask.

In some embodiments, the signal wirings may include a first signal wiring, a second signal wiring, and a third signal wiring. The first signal wiring may be configured to apply a gate signal to the gate electrode. The second signal wiring may be electrically connected to the source region. The third signal wiring may be electrically connected to the drain region. The uneven portion may be on the surface of the interlayer insulating film between the first signal wiring, the second signal wiring, and the third signal wiring.

In some embodiments, the method may further include forming an additional insulating film on the interlayer insulating film between the signal wirings.

In some embodiments, the forming the additional insulating film may include: coating a photoresist material on the signal wirings; depositing an additional insulating material on the photoresist material and the interlayer insulating film; and removing the photoresist material.

In some embodiments, the uneven portion may include at least one concave portion.

In some embodiments, a depth of the concave portion may be 500 Å or more and 1000 Å or less.

According to an embodiment of the present disclosure, an electronic device may include: an input module; a memory storing at least one program; a processor operating by executing the at least one program; a display device; and a power module supplying power to the display device. The processor may be configured to control the input module to acquire data and to control the display device to visually display the data. The display device may include: a substrate; a thin-film transistor on the substrate; an interlayer insulating film on the thin-film transistor; and signal wirings on the interlayer insulating film. The signal wirings may be electrically connected to the thin-film transistor. A surface of the interlayer insulating film may include an uneven portion between the signal wirings.

According to an embodiment of the present disclosure, an electronic device may include a display device. The display device may include: a substrate; a thin-film transistor on the substrate; an interlayer insulating film on the thin-film transistor; and signal wirings on the interlayer insulating film. The signal wirings may be electrically connected to the thin-film transistor. A surface of the interlayer insulating film may include an uneven portion between the signal wirings.

### BRIEF DESCRIPTION OF THE DRAWINGS

The following drawings attached to this specification illustrate example embodiments of the present disclosure and, together with the detailed description of the present disclosure described below, serve to further clarify technical concepts of the present disclosure; therefore, the present disclosure should not be interpreted as being limited to matters described in such drawings:

FIG. 1 is a plan view schematically illustrating an embodiment of a display device according to an embodiment of the present disclosure;

FIG. 2 is a block diagram schematically showing the structure of the display device of FIG. 1;

FIG. 3 is an equivalent circuit diagram of a sub-pixel of the display device of FIG. 1;

FIG. 4 schematically shows an example of a cross-section taken along line I-I′ of FIG. 1;

FIG. 5 is an enlarged view schematically illustrating an enlarged example of A in FIG. 4.

FIG. 6 is an enlarged view schematically illustrating an enlarged example of B in FIG. 5.

FIG. 7 is an enlarged view schematically illustrating another example of B in FIG. 5.

FIG. 8 is an enlarged view schematically illustrating another example of B in FIG. 5.

FIG. 9 is an enlarged view schematically illustrating another example of B in FIG. 5.

FIGS. 10 to 17 are cross-sectional views schematically illustrating a method of manufacturing a display device according to an embodiment of the present disclosure.

FIG. 18 is a block diagram of an electronic device according to embodiments of the present disclosure.

FIG. 19 is a schematic diagram of an electronic device according to various embodiments.

### DETAILED DESCRIPTION

The present disclosure may undergo various modifications and have various embodiments, and specific embodiments are illustrated in the drawings and described in detail in the detailed description. The effects and features of the present disclosure and the method of achieving them will become clear with reference to the embodiments described in detail below together with the drawings. However, the present disclosure is not limited to the embodiments disclosed below and may be implemented in various forms.

In the embodiments below, the terms first, second, etc. are not used in a limiting sense but are used for the purpose of distinguishing one component from another.

In the embodiments below, singular expressions include plural expressions unless the context clearly indicates otherwise.

In the embodiments below, terms such as “include” or “have” mean that a feature or component described in the specification is present, but do not preclude the possibility of adding one or more additional features or components.

In the embodiments below, when a part such as a unit, region, or component is described as being above or on another part, this includes not only the case where it is directly above the other part, but also the case where another unit, region, component, etc. is interposed in between.

In the embodiments below, terms such as “connect” or “combine” do not necessarily mean a direct and/or fixed connection or combination of two members, unless the context clearly indicates otherwise, nor do they exclude the presence of another member between the two members.

In the drawings, the sizes of components may be exaggerated or reduced for the convenience of explanation. For example, the size and/or thickness of each component shown in the drawings are arbitrarily shown for the convenience of explanation, and therefore the present disclosure is not necessarily limited to what is shown.

Hereinafter, embodiments of the present disclosure will be described in detail with reference to the attached drawings. When describing with reference to the drawings, identical or corresponding components are given the same drawing reference numerals and redundant descriptions thereof will be omitted.

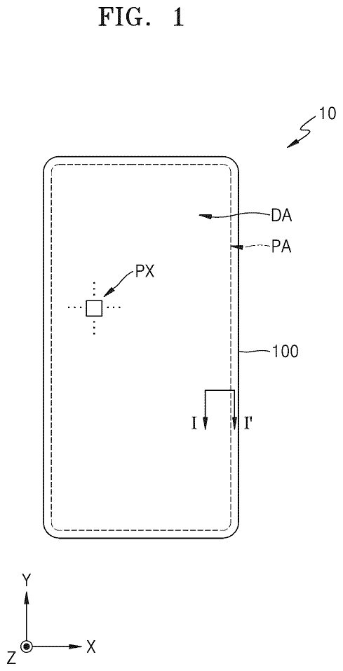

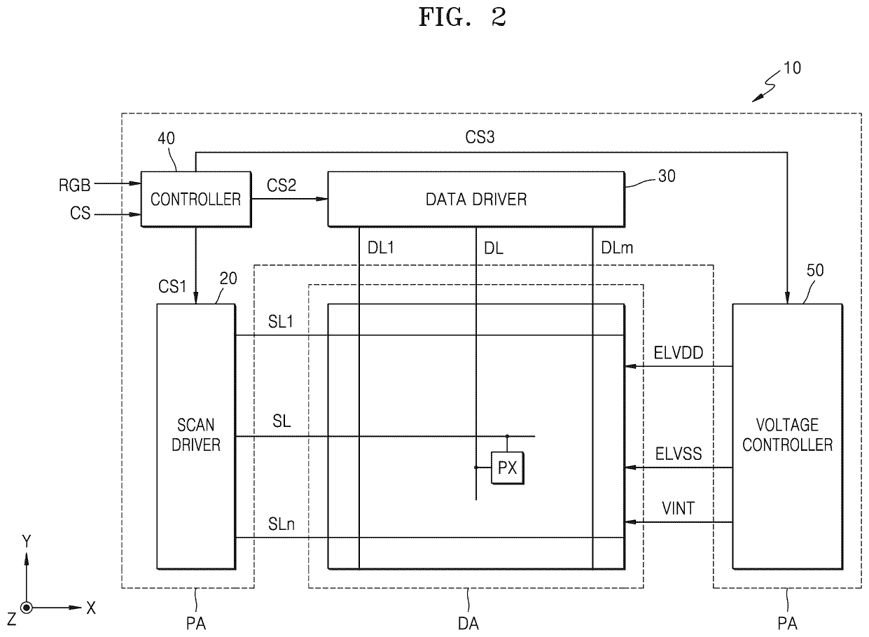

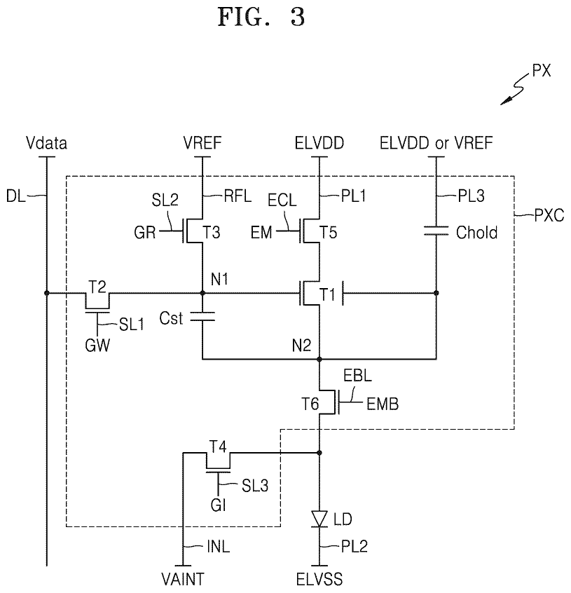

FIG. 1 is a plan view schematically illustrating an embodiment of a display device according to an embodiment of the present disclosure, FIG. 2 is a block diagram schematically illustrating the structure of the display device of FIG. 1, and FIG. 3 is an equivalent circuit diagram of one sub-pixel of the display device of FIG. 1.

First, referring to FIGS. 1 and 2, a display device 10 according to an embodiment of the present disclosure may include a substrate 100 including a display area DA for displaying an image and a peripheral area PA located outside the display area DA.

A display area DA may include a plurality of scan lines SL1, . . . , SLn extending along a first direction x, a plurality of data lines DL1, . . . , DLm extending along a second direction y perpendicular to the first direction x, and a plurality of sub-pixels PX. In this case, both m and n are natural numbers.

The wirings may be capable of applying electrical signals to multiple sub-pixels PX and may include multiple scan lines SL1, . . . , SLn, multiple data lines DL1, . . . , DLm, etc. The plurality of scan lines SL1, . . . , SLn may be arranged in multiple rows extending in the first direction x, for example, to transmit scan signals to sub-pixels PX, and the plurality of data lines DL1, . . . , DLm may be arranged in multiple columns extending in the second direction y, for example, to transmit data signals to the sub-pixels PX, and the plurality of sub-pixels PX may be positioned at intersections of the plurality of scan lines SL1, . . . , SLn and the plurality of data lines DL1, . . . , DLm.

Each sub-pixel PX may contain a light-emitting element that may emit red, green, blue, or white light. For example, each sub-pixel PX may include, but is not limited to, an organic light-emitting diode OLED as a light-emitting element.

The peripheral area PA may include a data driver 30 that provides data signals to the display area DA, a scan driver 20 that provides scan signals to the display area DA, a voltage controller 50 that controls voltages supplied to the display area DA, and a controller 40 that can control the data driver 30, scan driver 20, and voltage controller 50.

The voltage controller 50 can generate and control the first voltage ELVDD, the second voltage ELVSS, and the initialization voltage VAINT supplied to the display area DA.

The plurality of sub-pixels PX may be supplied with the first voltage ELVDD, the second voltage ELVSS, and the initialization voltage VAINT. For example, the first voltage ELVDD may be a positive voltage, and the second voltage ELVSS may be a negative voltage or ground voltage. That is, the second voltage ELVSS may have a lower level than the first voltage ELVDD.

The controller 40 can receive image signals RGB and control signals CS from the external source (e.g., a system board). The controller 40 can convert the data format of image signals RGB to match the interface specifications of the data driver 30 and generate image data (DATA). The controller 40 can provide image data (DATA) whose data format has been converted to the data driver 30.

The controller 40 can generate and output a first control signal CS1 and a second control signal CS2 in response to a control signal CS provided from an external source. The first control signal CS1 may be defined as a scan control signal, and the second control signal CS2 may be defined as a data control signal. The first control signal CS1 may be provided to the scan driver 20. A second control signal CS2 may be provided to the data driver 30.

The scan driver 20 can generate a plurality of scan signals in response to the first control signal CS1. A plurality of scan signals may be applied to the plurality of sub-pixels PX via the plurality of scan lines SL1, . . . , SLn.

The data driver 30 can generate a plurality of data voltages corresponding to image data (DATA) in response to the second control signal CS2. A plurality of data voltages may be applied to the plurality of sub-pixels PX via data lines DL1, . . . , DLm. The data driver 30 can simultaneously provide the data voltages generated on a sub-pixel row basis to data lines DL1, . . . , DLm for the plurality of sub-pixels PXs.

A plurality of sub-pixels PX can receive a plurality of data voltages in response to a plurality of scan signals. A plurality of sub-pixels PX may display an image by emitting light with a brightness corresponding to the plurality of data voltages. A plurality of sub-pixels PX may display the image by emitting light sequentially or simultaneously.

Referring to FIGS. 1 to 3, a sub-pixel PX may include a pixel circuit PXC and a light-emitting element LD. Additionally, a sub-pixel PX may be connected to a scan line SL (or gate line) and a data line DL. The scan lines SL may be one of the plurality of scan lines SL1, . . . , SLn of FIG. 2, and the data line DL may be one of the plurality of data lines DL1, . . . , DLm of FIG. 2. The scan lines SL may include a first scan line SL1, a second scan line SL2, a third scan line SL3, a first light-emission control line ECL, and a second light-emission control line EBL.

Driving signals may be applied to the scan line SL and data line DL. A first scan signal GW may be applied to a first scan line SL1, a second scan signal GR may be applied to a second scan line SL2, and a third scan signal GI may be applied to a third scan line SL3. A first light-emission control signal EM is applied to a first light-emission control line ECL, a second light-emission control signal EMB is applied to a second light-emission control line EBL, and a data signal Vdata (or data voltage) may be applied to a data line DL.

Additionally, the sub-pixel PX may be further connected to a first voltage line PL1, a second voltage line PL2, a third voltage line PL3, a reference voltage line RFL, and an initialization voltage line INL. Voltages may be applied to the first voltage line PL1, the second voltage line PL2, the third voltage line PL3, the reference voltage line RFL, and the initialization voltage line INL. The first voltage ELVDD may be applied to the first voltage line PL1, the second voltage ELVSS may be applied to the second voltage line PL2, the first voltage ELVDD or the reference voltage VREF may be applied to the third voltage line PL3, the reference voltage VREF may be applied to the reference voltage line RFL, and the initialization voltage VAINT may be applied to the initialization voltage line INL.

The voltage level of the first voltage ELVDD may be higher than the voltage level of the second voltage ELVSS. The voltage level of the reference voltage VREF may be equal to or different from the voltage level of the first voltage ELVDD. The voltage level of the initialization voltage VAINT may be lower than the voltage level of the first voltage ELVDD and higher than the voltage level of the second voltage ELVSS. However, the voltages are not limited to these, and the voltage levels of the voltages may vary depending on the product specifications.

Meanwhile, the pixel circuit PXC may include a first transistor T1 (or driving transistor), a second transistor T2, a third transistor T3, a fourth transistor T4, a fifth transistor T5, a sixth transistor T6, a first capacitor Cst (or storage capacitor), and a second capacitor Chold (or hold capacitor).

The first transistor T1 may be electrically connected between the first voltage line PL1 and the second node N2. For example, the first electrode of the first transistor T1 may be connected to the first voltage line PL1 via the fifth transistor T5, and the second electrode of the first transistor T1 may be connected to the second node N2. For example, the first electrode may be a source electrode and the second electrode may be a drain electrode. However, this is not limited to the first electrode being a drain electrode and the second electrode being a source electrode.

The gate electrode of the first transistor T1 may be connected to the first node N1. Additionally, the first transistor T1 may further include a lower electrode (or a second gate electrode) corresponding to the gate electrode. The first transistor T1 can supply driving current to the light-emitting element LD or control the amount of driving current flowing from the first voltage line PL1 to the light-emitting element LD. For example, the first transistor T1 may supply a driving current corresponding to the voltage of the first node N1 to the light-emitting element LD.

The second transistor T2 may be electrically connected between the data line DL and the first node N1. The gate electrode of the second transistor T2 may be connected to the first scan line SL1. The second transistor T2 may be turned on in response to the first scan signal GW of the first scan line SL1. In case that the second transistor T2 is turned on, the data signal Vdata of the data line DL may be transmitted to the first node N1.

The third transistor T3 may be electrically connected between the reference voltage line RFL and the first node N1. The gate electrode of the third transistor T3 may be connected to the second scan line SL2. The third transistor T3 may be turned on in response to the second scan signal GR of the second scan line SL2. In case that the third transistor T3 is turned on, the reference voltage VREF may be transmitted to the first node N1.

The fourth transistor T4 may be electrically connected between the anode electrode of the light-emitting element LD and the initialization voltage line INL. The gate electrode of the fourth transistor T4 may be connected to the third scan line SL3. The fourth transistor T4 may be turned on in response to the third scan signal GI of the third scan line SL3. In case that the fourth transistor T4 is turned on, the initialization voltage VAINT may be transmitted to the anode electrode of the light-emitting element LD.

The fifth transistor T5 may be electrically connected between the first voltage line PL1 and the first transistor T1. The gate electrode of the fifth transistor T5 may be connected to the first light-emission control line ECL. The fifth transistor T5 may be turned on in response to the first light-emission control signal EM of the first light-emission control line ECL.

The sixth transistor T6 may be electrically connected between the second node N2 and the anode electrode of the light-emitting element LD. The gate electrode of the sixth transistor T6 may be connected to the second light-emission control line EBL. The sixth transistor T6 may be turned on in response to the second light-emission control signal EMB of the second light-emission control line EBL.

In case that the fifth transistor T5 and the sixth transistor T6 are turned on, a current path may be formed through which a driving current may flow from the first voltage line PL1 to the second voltage line PL2 via the pixel circuit PXC and the light-emitting element LD.

The first capacitor Cst may be formed or electrically connected between the first node N1 and the second node N2. A voltage corresponding to the data voltage Vdata may be stored in the first capacitor Cst.

A second capacitor Chold may be formed or electrically connected between the third voltage line PL3 and the second node N2. The second capacitor Chold can stabilize the voltage of the second node N2. The third voltage line PL3 can be applied with the first voltage ELVDD or the reference voltage VREF. For example, when the first voltage ELVDD is applied to the third voltage line PL3, the third voltage line PL3 may be electrically connected to the first voltage line PL1 or integrally formed with the first voltage line PL1. However, the third voltage line PL3 is not limited thereto.

The light-emitting element LD may be electrically connected between the sixth transistor T6 and the second voltage line PL2. For example, the light-emitting element LD can be connected in the forward direction between the second node N2 and the second voltage line PL2. When a driving current is supplied from the first transistor T1, the light-emitting element LD can emit light with a brightness corresponding to the driving current.

In an embodiment, the light-emitting element LD may include an organic light-emitting diode OLED. In another embodiment, the light-emitting element LD may include at least one inorganic light-emitting diode. The type, size, and/or number of light-emitting elements LD may vary depending on the embodiment.

Thin-film transistors T may be N-type transistors, but they are not limited thereto. For example, at least one of the thin-film transistors T may be changed to a P-type transistor. Additionally, the voltage levels of driving signals for controlling the operation of the transistor may be set depending on the type of each transistor.

The thin-film transistor T may include an oxide semiconductor and/or low-temperature polycrystalline silicon (LTPS). For example, at least one transistor including the first transistor T1 may be an oxide semiconductor transistor including an oxide semiconductor.

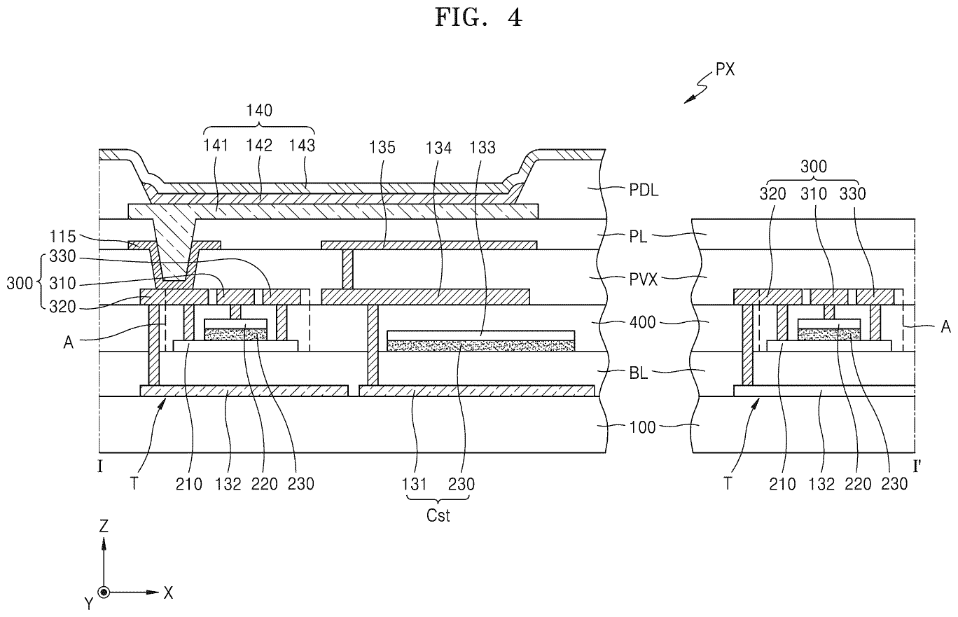

FIG. 4 is a cross-sectional view schematically illustrating an embodiment of the I-I′ cross-section of FIG. 1. The thin-film transistor T may include a driving transistor T1 (see T1 in FIG. 3) and other switching transistors.

Meanwhile, a base metal layer 131, 132 that limits and/or blocks light may be located below the capacitor Cst and the thin-film transistor T. The base metal layer 131, 132 may have a laminated structure of at least a first layer and a second layer of different materials. The first layer may include Al, and the second layer may include Ti.

For example, a first base metal layer 131 is arranged in the capacitor Cst region, and a second base metal layer 132 is arranged in the driving transistor T1 region, so that each can perform a light-blocking function to limit and/or prevent light from entering or exiting through the substrate 100. In addition, the first base metal layer 131 may be electrically connected to the second metal layer 134, and the second base metal layer 132 may be electrically connected to the second signal wiring 320 of the thin-film transistor T to provide electrical characteristics.

In some embodiments, a thin-film transistor T and a capacitor Cst are provided on a substrate 100, and a light-emitting element 140 electrically connected to the thin-film transistor T may be positioned thereon.

The substrate 100 may be made of a transparent glass material containing SiO₂ as its main component. However, it is not necessarily limited to this, and the substrate 100 may be formed of a transparent plastic material. Plastic materials may be polyethersulfone (PES), polyacrylate (PAR), polyetherimide (PEI), polyethylene naphthalate (PEN), polyethylene terephthalate (PET), polyphenylene sulfide (PPS), polyallylate, polyimide, polycarbonate (PC), cellulose triacetate (TAC), cellulose acetate propionate (CAP), etc.

A buffer layer BL may be formed on the substrate 100. The buffer layer BL may contain an inorganic material such as silicon oxide, silicon nitride, silicon oxynitride, aluminum oxide, aluminum nitride, titanium oxide or titanium nitride, or an organic material such as polyimide, polyester or acrylic, and may be formed by a plurality of laminates of the exemplified materials.

The first base metal layer 131 and the second base metal layer 132 are formed on the substrate 100 and may be covered by a buffer layer BL. The first base metal layer 131 and the second base metal layer 132 may be composed of multiple layers to reduce resistance. For example, the first base metal layer 131 and the second base metal layer 132 may include a first layer containing Al and a second layer including Ti on top of the first layer.

A thin-film transistor T includes a semiconductor layer 210, a gate electrode 220, and signal wirings 300, and may be positioned on the buffer layer BL.

The semiconductor layer 210 may include, for example, an oxide semiconductor. For example, the semiconductor layer 210 may include an oxide of a material selected from group 12, 13, and 14 metal elements such as zinc (Zn), indium (In), gallium (Ga), tin (Sn), cadmium (Cd), and germanium (Ge), and combinations thereof. For example, the semiconductor layer 210 may include G-I-Z-O[(In₂O₃)ₐ(Ga₂O₃)_{b}(ZnO)_{c}](a, b, and c are real numbers satisfying the conditions of a≥0, b≥0, and c>0, respectively).

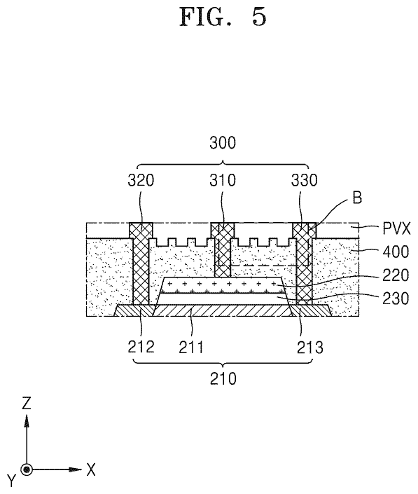

The semiconductor layer 210, as shown in FIG. 5 of the present application, may include a channel region 211 and a source region 212 and a drain region 213 respectively arranged on opposite sides of the channel region 211.

The gate electrode 220 may be positioned on the semiconductor layer 210 with a gate insulating film 230 interposed therebetween. In some embodiments, the gate electrode 220 may be positioned to overlap the channel region 211 with a gate insulating film 230 therebetween.

The gate electrode 220 may be formed as a single layer or a multilayer using one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

Additionally, the gate electrode 220 may have the same structure as the base metal layer 131, 132. That is, the gate electrode 220 may be formed of a laminated structure having at least a first layer including Al and a second layer including Ti on the first layer.

The gate insulating film 230 may be formed as a multilayer or single layer film made of an inorganic material such as silicon oxide and/or silicon nitride.

The signal wirings 300 are positioned on an interlayer insulating film 400 and may be electrically connected to the thin-film transistor T.

The signal wirings 300 may include a first signal wiring 310 that applies a gate signal to the gate electrode 220, a second signal wiring 320 electrically connected to the source region 212, and a third signal wiring 330 electrically connected to the drain region 213.

The first signal wiring 310, the second signal wiring 320, and the third signal wiring 330 may be formed on the semiconductor layer 210 with the interlayer insulating film 400 interposed therebetween. In some embodiments, the first signal wiring 310 may be formed on the gate electrode 220, and the second signal wiring 320 and the third signal wiring 330 may be electrically connected to opposite ends of the semiconductor layer 210 doped with N-type or P-type impurities, respectively.

The first signal wiring 310, the second signal wiring 320, and the third signal wiring 330 may be formed as a single layer or a multilayer using one or more materials selected from aluminum (Al), platinum (Pt), palladium (Pd), silver (Ag), magnesium (Mg), gold (Au), nickel (Ni), neodymium (Nd), iridium (Ir), chromium (Cr), lithium (Li), calcium (Ca), molybdenum (Mo), titanium (Ti), tungsten (W), and copper (Cu).

The interlayer insulating film 400 may be placed on a thin-film transistor T. The interlayer insulating film 400 may include an uneven portion 410 on the surface between the signal wirings 300.

The interlayer insulating film 400 may be formed as a multilayer or single layer film made of an inorganic material. For example, the inorganic material may be a metal oxide or a metal nitride, and in some embodiments, the inorganic material may include silicon oxide (SiO₂), silicon nitride (SiNₓ), silicon oxynitride (SiON), aluminum oxide (Al₂O₃), titanium oxide (TiO₂), tantalum oxide (Ta₂O₅), hafnium oxide (HfO₂), or zirconium oxide (ZrO₂).

A passivation layer PVX may be positioned on the first signal wiring 310, the second signal wiring 320, and the third signal wiring 330. The passivation layer PVX may include an organic insulator such as acrylic, benzocyclobutene(BCB), or hexamethyldisiloxane(HMDSO).

The light-emitting element 140 including a pixel electrode 141, a counter electrode 143, and an intermediate layer 142 interposed between the pixel electrode 141 and the counter electrode 143 may be positioned on a passivation layer PVX. The light-emitting element 140 may be an organic light-emitting element.

The pixel electrode 141 may be electrically connected to the second signal wiring 320 of the thin-film transistor T through, for example, the contact layer 115. In some embodiments, the contact layer 115 may be positioned on a passivation layer PVX, and a planarization layer PL may be formed on the contact layer 115. The passivation layer PVX has an opening that exposes, for example, a second signal wiring 320 of a thin-film transistor T, and the contact layer 115 may make contact with the second signal wiring 320 through the opening.

The planarization layer PL contains an organic insulating material such as acrylic, benzocyclobutene(BCB), or hexamethyldisiloxane(HMDSO), and can play a role in planarizing the curvature caused by the lower layers.

The pixel electrode 141 is positioned on a planarization layer PL and can be electrically connected to the underlying contact layer 115 through a via hole.

The pixel electrode 141 may be a (semi)transparent electrode or a reflective electrode. In case that the pixel electrode 141 is a (semi)transparent electrode, it may include, for example, ITO, IZO, ZnO, In₂O₃, IGO, or AZO. In case that the pixel electrode 141 is a reflective electrode, it may have a reflective film formed of Ag, Mg, Al, Pt, Pd, Au, Ni, Nd, Ir, Cr, and compounds thereof, and a layer formed of ITO, IZO, ZnO, In₂O₃, IGO, or AZO. Of course, the present disclosure is not limited to this, and the pixel electrode 141 may include various materials, and its structure may also be modified in various ways, such as being single-layered or multi-layered.

A pixel-defining layer PDL may be placed on top of the planarization layer PL. The pixel-defining layer PDL serves to define a pixel by having an opening that exposes at least the central portion of the pixel electrode 141. In addition, as shown in FIG. 5, the pixel-defining layer PDL limits and/or prevents arcs and the like from occurring at the edge of the pixel electrode 141 by increasing the distance between the edge of the pixel electrode 141 and the counter electrode 143 above the pixel electrode 141. Such pixel-defining layers PDLs may include organic insulators such as polyimide or hexamethyldisiloxane(HMDSO).

The intermediate layer 142 of the light-emitting element 140 includes a light-emitting layer. The light-emitting layer may include a polymer or low-molecular organic material that emits light of a preset color. Additionally, the intermediate layer 142 may include at least one functional layer among a hole transport layer (HTL), a hole injection layer (HIL), an electron transport layer (ETL), and an electron injection layer (EIL). Such functional layers may contain organic materials. Meanwhile, some of the layers forming the intermediate layer 142, for example, the functional layer(s), may be formed integrally across the plurality of light-emitting elements 140.

The counter electrode 143 may be arranged to cover the display area DA. The counter electrode 143 can be formed integrally with a plurality of light-emitting elements 140 and correspond to a plurality of pixel electrodes 141. These counter electrodes 143 may be (semi)transparent electrodes or reflective electrodes.

In case that the counter electrode 143 is a (semi)transparent electrode, it may have a layer formed of a metal having a small work function, e.g., Li, Ca, LiF/Ca, LiF/Al, Al, Ag, Mg, and compounds thereof, and a (semi)transparent conductive layer such as ITO, IZO, ZnO, or In₂O₃. In case that the counter electrode 143 is a reflective electrode, it may have a layer formed of Li, Ca, LiF/Ca, LiF/Al, Al, Ag, Mg, and compounds thereof. Of course, the composition and material of the counter electrode 143 are not limited to this and various modifications are possible.

Although not shown in the drawing, an encapsulation layer (not shown) may be located on top of the counter electrode 143. The encapsulation layer (not shown) serves to protect the light-emitting element 140 from moisture or oxygen from the external source. To this end, the encapsulation layer (not shown) has a shape that extends not only to the display area DA where the light-emitting element 140 is located, but also to the peripheral area PA outside the display area DA. These encapsulation layers (not shown) may have a multilayer structure. For example, the encapsulation layer (not shown) may include a first inorganic encapsulation layer, an organic encapsulation layer, and a second inorganic encapsulation layer, which are sequentially laminated.

The first inorganic encapsulation layer may include silicon oxide, silicon nitride and/or silicon oxynitride. Since the first inorganic encapsulation layer is formed along the structure below it, its upper surface may not be flat.

The organic encapsulation layer covers the first inorganic encapsulation layer and has a sufficient thickness so that the upper surface of the organic encapsulation layer may be substantially flat over the entire display area DA. These organic encapsulation layers may include polyethylene terephthalate, polyethylene naphthalate, polycarbonate, polyimide, polyethylene sulfonate, polyoxymethylene, polyarylate, hexamethyldisiloxane, acrylic resins (e.g., polymethyl methacrylate, polyacrylic acid, etc.) or any combination thereof.

The second inorganic encapsulation layer covers the organic encapsulation layer and may include silicon oxide, silicon nitride and/or silicon oxynitride, among others. The second inorganic encapsulation layer may extend outward beyond the organic encapsulation layer and come into contact with the first inorganic encapsulation layer, thereby limiting and/or preventing the organic encapsulation layer from being exposed.

Meanwhile, the second base metal layer 132 may be positioned below the thin-film transistor T close to the light-emitting element 140. The second base metal layer 132 performs a light-blocking function that blocks light from entering or exiting through the substrate 100, and at the same time, is connected to the second signal wiring 320 to stabilize the saturation characteristics of the second signal wiring 320 and the third signal wiring 330.

The capacitor Cst may include a first capacitor C1 and a second capacitor C2.

The first capacitor C1 may be formed of a first base metal layer 131 and a first metal layer 133 that overlap each other with a buffer layer BL therebetween. The first metal layer 133 may be formed of the same material in the same layer as the gate electrode 220.

The second capacitor C2 may be formed of a first base metal layer 131 composed of multiple layers, although not shown.

In such cases, two capacitors C1 and C2 may be formed in a stacked configuration within the same area on the plane, thereby increasing the capacitor Cst value.

Two capacitors C1 and C2 may be formed in a stacked configuration without increasing the space occupancy on the plane, thereby increasing the capacitor Cst value and improving the stability of the display device 10.

Peripheral circuits arranged in the peripheral area PA may be electrically connected to each of the pixel circuits that drive the sub-pixels PX. A gate driving circuit, a terminal section, a driving voltage supply line, and a common voltage supply line may be positioned in the peripheral area PA.

The peripheral circuits of the peripheral area PA may include a plurality of thin-film transistors T.

The outer inspection unit including the peripheral circuit of the peripheral area PA may have the thin-film transistor T on the substrate 100 with the thin-film transistor T placed similar to the display area DA. In some embodiments, a buffer layer BL may be disposed on the substrate 100, a thin-film transistor T including the semiconductor layer 210, the gate electrode 220, and signal wirings 300 may be disposed on the buffer layer BL, and the interlayer insulating film 400 may be disposed on the thin-film transistor T.

The semiconductor layer 210 may include the channel region 211, and the source region 212 and the drain region 213 respectively arranged on opposite sides of the channel region 211. The gate electrode 220 may be positioned on the semiconductor layer 210 with a gate insulating film 230 therebetween.

The signal wirings 300 are positioned on the interlayer insulating film 400 and may include a first signal wiring 310 that applies a gate signal to the gate electrode 220, a second signal wiring 320 that is electrically connected to the source region 212, and a third signal wiring 330 that is electrically connected to the drain region 213.

The first signal wiring 310, the second signal wiring 320, and the third signal wiring 330 may be formed on the semiconductor layer 210 with the interlayer insulating film 400 therebetween.

The interlayer insulating film 400 may include an uneven portion 410 on the surface between the signal wirings 300.

A passivation layer PVX may be formed on the first signal wiring 310, the second signal wiring 320, and the third signal wiring 330, and a planarization layer PL may be formed on the passivation layer PVX.

In order to increase the resolution of the display device 10, the spacing between signal wirings 300 connected to the source region 212, the drain region 213, and the gate electrode 220 may be narrowed. Due to this, the display device 10 may become more vulnerable to current leakage problems, and thus the reliability of the display device 10 may be reduced.

To limit and/or solve the above problem, according to example embodiments, a method is described in which an uneven portion 410 is disposed on the interlayer insulating film 400 between the signal wirings 300 respectively connected to the source region 212, the drain region 213, and a gate electrode 220 to increase the surface resistance between wirings.

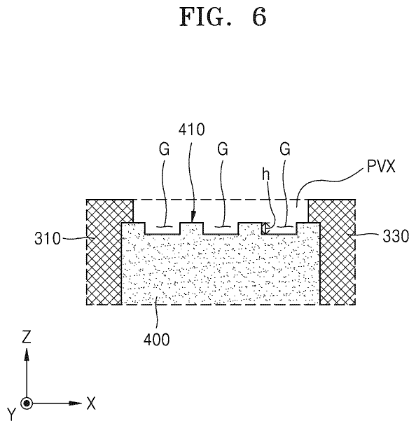

FIG. 5 is an enlarged view schematically illustrating an enlarged example of A in FIG. 4, and FIG. 6 is an enlarged view schematically illustrating an enlarged example of B in FIG. 5.

Referring to FIGS. 5 and 6, the interlayer insulating film 400 may include an uneven portion 410 on the surface between the first signal wiring 310, the second signal wiring 320, and the third signal wiring 330.

The interlayer insulating film 400 may be disposed on a thin-film transistor T on the substrate 100. Signal wirings 300 electrically connected to a thin-film transistor T may be disposed on the interlayer insulating film 400. The interlayer insulating film 400 may include an uneven portion 410 on the surface of the interlayer insulating film 400 between the signal wirings 300.

The thin-film transistor T may include a semiconductor layer 210, a gate insulating film 230 on the channel region 211 of the semiconductor layer 210, and a gate electrode 220 positioned to overlap the channel region 211 with the gate insulating film 230 between the gate electrode 220 and the channel region 211.

The semiconductor layer 210 may include the source region 212 and the drain region 213 respectively arranged on opposite sides of the channel region 211.

The signal wirings 300 may include a first signal wiring 310 that applies a signal to the gate electrode 220, a second signal wiring 320 electrically connected to the source region 212, and a third signal wiring 330 electrically connected to the drain region 213.

The interlayer insulating film 400 may include an uneven portion 410 that has at least one concave portion G on its surface and is disposed between the first signal wiring 310, the second signal wiring 320, and the third signal wiring 330.

Due to the uneven portion 410 of the interlayer insulating film 400 between the signal wirings 300, the distance between the signal wirings 300, e.g., the distance over which current flows from one signal wiring to another, may be increased. In some embodiments, the leakage current between the signal wirings 300 flows along the surface of the interlayer insulating film 400, and the current path may be extended by the uneven portion 410.

As the current path, which is the distance over which current flows from one signal wiring to another, increases, the surface resistance between the signal wirings 300 may increase. Due to this, current leakage between signal wirings 300 can be alleviated and/or prevented.

The uneven portion 410 may include at least one concave portion G. In case that the distance between signal wirings 300 is the same, the greater the number of concave portions G and the deeper the depth h of the concave portions G, the longer the path through which current flows from one signal wiring to another, and thus the surface resistance between the signal wirings 300 may increase. The depth h of the concave portion G may be, for example, 500 Å or more and 1000 Å or less.

FIG. 6 illustrates an uneven portion 410 of the interlayer insulating film 400 between the first signal wiring 310 and the third signal wiring 330. The uneven portion 410 is illustrated as having three concave portions G, but the number of concave portions G is not limited thereto.

The depth h of the concave portions G is illustrated to be the same for each of the plurality of concave portions G, but is not limited thereto, and the depth h of each of the plurality of concave portions G may be different.

The uneven portion 410 between the first signal wiring 310 and the second signal wiring 320, which is not shown in FIG. 6, may have a shape identical to or symmetrical to the uneven portion 410 between the first signal wiring 310 and the third signal wiring 330 shown in FIG. 6, or it may have a different shape. That is, the uneven portion 410 between the first signal wiring 310 and the second signal wiring 320 and the uneven portion 410 between the first signal wiring 310 and the third signal wiring 330 are not necessarily identical or symmetrical in shape.

In FIGS. 5 and 6, the bottom of the concave portion G of the uneven portion 410 is illustrated as forming a 90° angle with the depth h of the concave portion G, but this is not limited thereto, and the uneven portion 410 may include a concave portion G at least partially having a curve. Additionally, as an embodiment, the uneven portion 410 may include a concave portion G having an embossed shape.

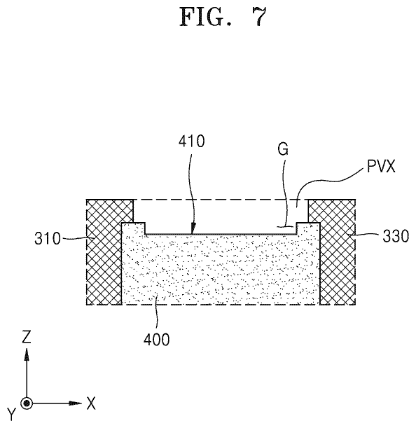

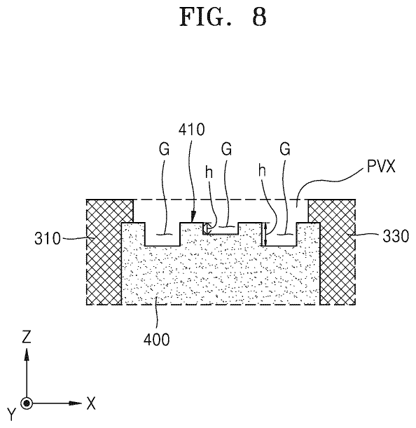

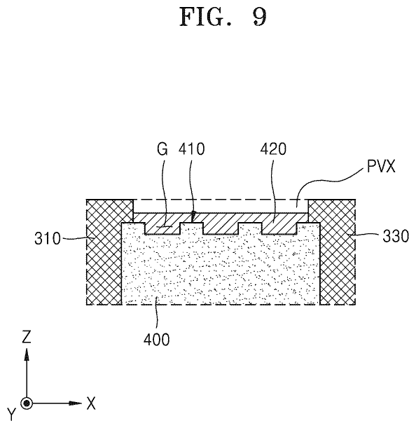

FIG. 7 is an enlarged view schematically illustrating another embodiment of an enlarged view of B in FIG. 5, FIG. 8 is an enlarged view schematically illustrating another embodiment of an enlarged view of B in FIG. 5, and FIG. 9 is an enlarged view schematically illustrating yet another embodiment of an enlarged view of B in FIG. 5.

Referring to FIG. 7, the interlayer insulating film 400 in an embodiment may include a single concave portion G. When the uneven portion 410 of the interlayer insulating film 400 has a concave portion G between two adjacent signal wirings 300, for example, between the first signal wiring 310 and the third signal wiring 330, the greater the depth h of the concave portion G, the longer the path through which current can flow between the first signal wiring 310 and the third signal wiring 330, and thus, the surface resistance of the interlayer insulating film 400 between the first signal wiring 310 and the third signal wiring 330 may increase.

Referring to FIG. 8, the interlayer insulating film 400 may include a plurality of concave portions G. At least two of the plurality of concave portions G may have different depths and/or widths.

As illustrated in FIG. 8, the uneven portion 410 of the interlayer insulating film 400 of an embodiment may include three concave portions G. Each concave portion G may have a different depth h, and the width of the concave portion G may be different in the direction parallel to the shortest distance connecting two adjacent signal wirings 300.

The greater the number of concave portions G, the longer the path through which current may flow between two adjacent signal wirings 300, for example, between the first signal wiring 310 and the third signal wiring 330. In some embodiments, the leakage current between the two signal wirings 300 flows along the surface of the interlayer insulating film 400, and the current path may be lengthened by the uneven portion 410. Accordingly, the surface resistance of the interlayer insulating film 400 between the first signal wiring 310 and the third signal wiring 330 may increase.

Referring to FIG. 9, the interlayer insulating film 400 may further include an additional insulating film 420 covering the uneven portion 410.

In addition to arranging the uneven portion 410 to prevent and/or alleviate current leakage between signal wirings 300, the interlayer insulating film 400 may also include an additional insulating film 420.

The additional insulating film 420 may be composed of a material with a low permittivity, which does not effectively transmit electric fields, making it more difficult for current to flow between the signal wirings 300. The permittivity of the additional insulating film 420 may be, for example, at most 4.

In addition, since the additional insulating film 420 is formed of a material having a low permittivity, the parasitic capacitance between the signal wirings 300 may be reduced. In other words, since an additional insulating film 420 having a low permittivity is filled between the signal wirings 300, the parasitic capacitance between the signal wirings 300 may be reduced.

The additional insulating film 420 may have sufficient insulating properties and a thickness that does not significantly increase the overall thickness of the display device 10. The thickness of the additional insulating film 420 may be, for example, 500 Å or more and 1000 Å or less.

The additional insulating film 420 can protect the signal wirings 300 or the uneven portion 410 from contaminants. The additional insulating film 420 may be formed of a material whose lattice structure closely matches with the layer including the passivation layer PVX and the uneven portion 410. This can alleviate and/or prevent current leakage, reduce defects or impurities in the interlayer insulating film 400, and improve the electrical characteristics, lifespan, and stability of the display device 10.

In FIGS. 7 to 9, the bottom of the concave portion G of the uneven portion 410 is illustrated as forming a 90° angle with the depth h of the concave portion G, but this is not limited to this, and the uneven portion 410 may include a concave portion G that at least partially has a curve. Additionally, as an embodiment, the uneven portion 410 may include a concave portion G having an embossed shape.

Except for the uneven portion 410 and the concave portion G in FIGS. 7 to 9, other configurations may be applied in the same manner as described in FIGS. 1 to 6. Additionally, the depth h of the concave portion G in FIGS. 7 to 9 may be 500 Å or more and 1000 Å or less as described in FIGS. 5 and 6.

In addition, the uneven portion 410 between the first signal wiring 310 and the third signal wiring 330 is illustrated in FIGS. 7 to 9, and the description in FIGS. 7 to 9 may be equally applied to the uneven portion 410 between the first signal wiring 310 and the second signal wiring 320. However, the uneven portion 410 between the first signal wiring 310 and the third signal wiring 330 in FIGS. 7 to 9 and the uneven portion 410 between the first signal wiring 310 and the second signal wiring 320 not described in FIGS. 7 to 9 may have the same or symmetrical shape, or they may have a different, non-symmetrical shape.

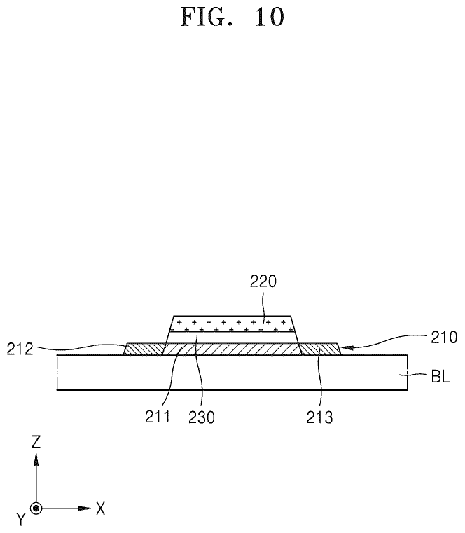

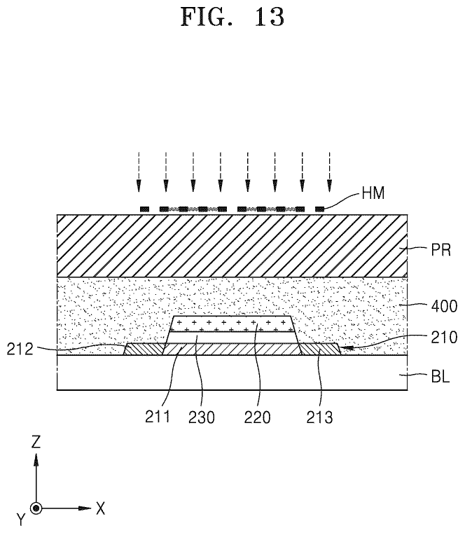

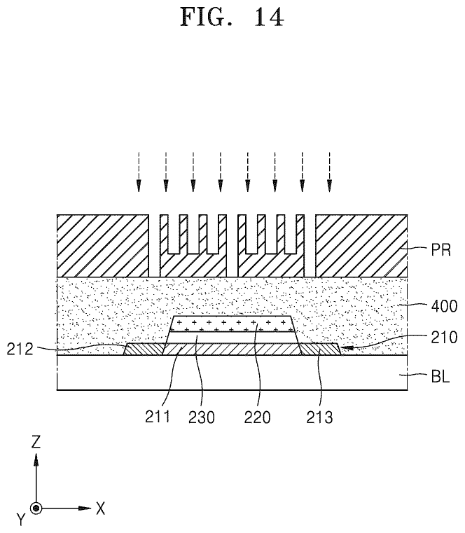

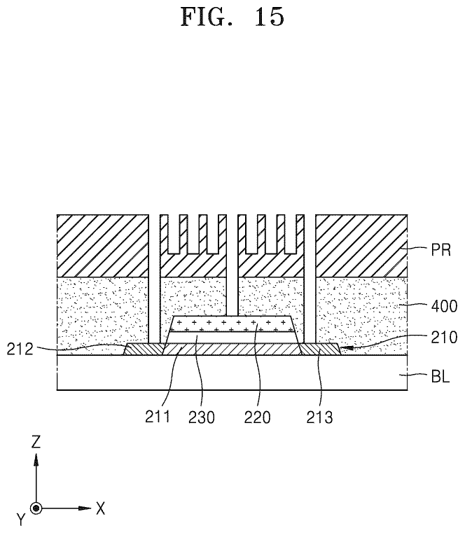

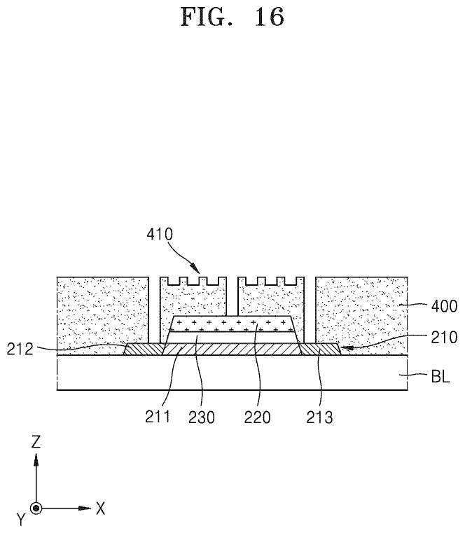

FIGS. 10 to 17 are cross-sectional views schematically illustrating a method of manufacturing a display device according to an embodiment of the present disclosure.

A display device 10 may be manufactured through: forming a semiconductor layer 210, a gate insulating film 230, and a gate electrode 220 on the substrate 100 to form a thin-film transistor T; forming the interlayer insulating film 400 on the thin-film transistor T; forming an uneven portion 410 on the surface of the interlayer insulating film 400, and forming signal wirings 300 electrically connected to the thin-film transistor T on the interlayer insulating film 400.

Referring to FIG. 10, first, a thin-film transistor T may be formed on the substrate 100. As an embodiment, after positioning a buffer layer BL on the substrate 100, a thin-film transistor T may be formed on the buffer layer BL.

In some embodiments, after forming a semiconductor layer 210 on a buffer layer BL, a gate insulating film 230 may be formed on an area of the semiconductor layer 210, and a gate electrode 220 may be formed on the gate insulating film 230 to form a thin-film transistor T.

After the forming a thin-film transistor T, the source region 212 and the drain region 213 can be formed by doping impurities into the semiconductor layer 210 using the gate electrode 220 as a mask.

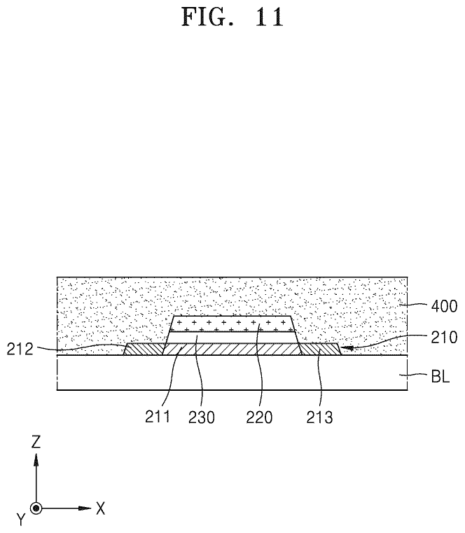

Referring to FIG. 11, after the forming a thin-film transistor, forming the interlayer insulating film 400 on a thin-film transistor T may be performed.

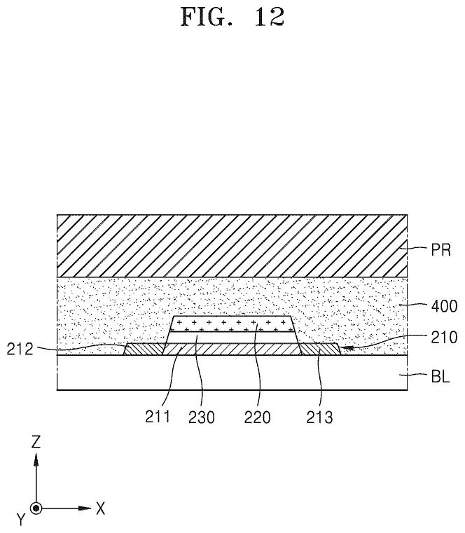

FIGS. 12 to 16 illustrate forming an uneven portion 410 on the surface of the interlayer insulating film 400 after the forming the interlayer insulating film 400.

The forming an uneven portion 410 on the surface of the interlayer insulating film 400 may first form a photoresist layer PR by coating a photoresist material on the interlayer insulating film 400.

A photoresist pattern may be formed on the formed photoresist layer PR using a half-tone mask HM.

The half-tone mask HM can adjust the width and depth h of the concave portion G of the uneven portion 410 by controlling the transmittance and width for each area to achieve the desired design. By using a half-tone mask HM when forming a photoresist pattern, additional mask increases can be avoided, simplifying the process and reducing manufacturing costs and processing time.

As an embodiment, a half-tone mask HM may be prepared with a high transmittance in areas where signal wirings 300 are to be formed, and a low transmittance in areas where a concave portion G of the uneven portion 410 is to be formed. In some embodiments, a half-tone mask HM may be disposed in areas where the concave portion G of a low-transmittance uneven portion 410 is to be formed between areas where high-transmittance signal wirings 300 are to be formed.

A photoresist pattern may be formed by performing exposure and development processes on a photoresist layer PR while placing a half-tone mask HM on the photoresist layer PR.

After forming the photoresist pattern, the interlayer insulating film 400 may be patterned using the photoresist pattern as a mask, e.g., by performing an etching process.

In case that stripping is performed to remove the remaining photoresist pattern after patterning the interlayer insulating film 400, areas where uneven portions 410 and signal wirings 300 are formed may be formed on the surface of the interlayer insulating film 400.

By controlling the transmittance of each area in the half-tone mask HM, the uneven portion 410 may be made in an embossed shape, and by controlling the width and transmittance of each area in the half-tone mask HM, at least the uneven portion 410 may be made to include at least one concave portion G.

In addition, the depth h of the concave portion G in the uneven portion 410 may be adjusted by controlling the transmittance of the half-tone mask HM, and the light intensity in the exposure process, and other factors. As an embodiment, the depth h of the concave portion G may be 500 Å or more and 1000 Å or less.

When the uneven portion 410 is formed in the interlayer insulating film 400, the interlayer insulating film 400 may be patterned to expose one area of the source region 212, the drain region 213, and the gate electrode 220 so that the signal wirings 300 are electrically connected to the source region 212, the drain region 213, and the gate electrode 220.

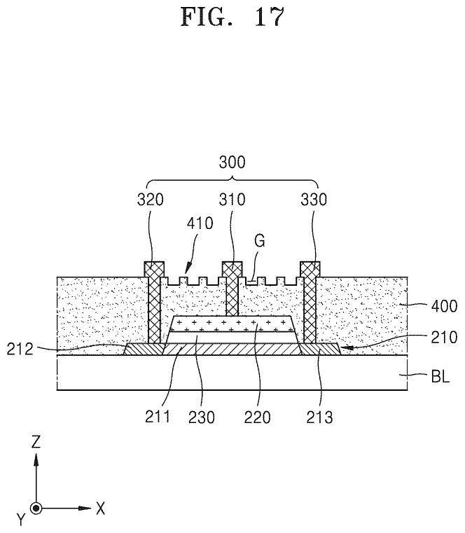

Referring to FIG. 17, after the formation of the uneven portion 410, signal wirings 300 electrically connected to the thin-film transistor T may be formed on the interlayer insulating film 400.

When an uneven portion 410 is formed on the interlayer insulating film 400, signal wirings 300 may be formed on the interlayer insulating film 400 patterned so that one area of the source region 212, the drain region 213, and the gate electrode 220 is exposed using an appropriate half-tone mask HM having different transmittances for each area.

The half-tone mask HM forms low-transmittance regions between high-transmittance regions, so that an uneven portion 410 may be placed between the exposed portions of the source region 212, the drain region 213, and the gate electrode 220 in the interlayer insulating film 400. The uneven portion 410 may be disposed between the signal wirings 300.

In some embodiments, the signal wirings 300 may include a first signal wiring 310 that applies a gate signal to the gate electrode 220, a second signal wiring 320 electrically connected to the source region 212, and a third signal wiring 330 electrically connected to the drain region 213.

That is, the uneven portion 410 may be formed on the surface of the interlayer insulating film 400 between the first signal wiring 310, the second signal wiring 320, and the third signal wiring 330.

Although not shown, after the formation of the signal wirings 300, an additional insulating film 420 may be additionally formed on the interlayer insulating film 400 between the signal wirings 300.

The forming the additional insulating film 420 may include coating a photoresist material on the signal wirings 300, depositing an additional insulating material on the photoresist material and the interlayer insulating film 400, and removing the photoresist material.

The additional insulating film 420 can protect the uneven portion 410 and signal wirings 300 from contaminants, and as an embodiment, the thickness of the additional insulating film 420 may be 500 Å or more and 1000 Å or less.

The additional insulating film 420 is made of a material with low permittivity and can alleviate and/or prevent current leakage between signal wirings 300. As an embodiment, the permittivity of the additional insulating film 420 may be 4 or lower.

The display device 10 described above and the display device 10 manufactured by the manufacturing method described above form an uneven portion 410 on the surface of the interlayer insulating film 400 between the signal wirings 300, so that the leakage current between the signal wirings 300 flows along the surface of the interlayer insulating film 400, and the current path may be lengthened by the uneven portion 410. Due to this, the resistance between the signal wirings 300 increases, which may reduce the micro-current leakage.

Due to this, it is not necessary to perform a first article inspection (FCA) after the formation of a passivation layer PVX or a contact layer 115, and FCA inspection and repairs based on the inspection results may be performed early after the formation of signal wirings 300, thereby improving the yield of the display device 10 and reducing the cost.

The uneven portion 410 that increases the distance through which current flows between signal wirings 300 and thereby increases resistance may provide a display device 10 with improved reliability even when the distance between signal wirings 300 is shortened to meet the requirement of increased resolution.

The display device 10 according to an embodiment may be applied to various electronic devices 1000. An electronic device 1000 according to an embodiment includes the display device 10 described above, and may further include a module or device having additional functions in addition to the display device 10.

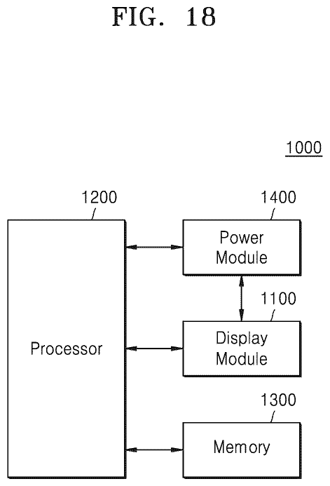

FIG. 18 is a block diagram of an electronic device according to an embodiment of the present disclosure. Referring to FIG. 18, an electronic device 1000 according to an embodiment may include a display module 1100, a processor 1200, a memory 1300, and a power module 1400.

The processor 1200 may include at least one of a central processing unit CPU, an application processor AP, a graphic processing unit GPU, a communication processor CP, an image signal processor ISP, and a controller.

Data information necessary for the operation of the processor 1200 or display module 1100 may be stored in the memory 1300. When the processor 1200 executes an application stored in the memory 1300, an image data signal and/or an input control signal is transmitted to the display module 1100, and the display module 1100 can process the received signal and output the image information through a display screen.

The power module 1400 may include a power supply module, such as a power adapter or a battery device, and a power conversion module that converts power supplied by the power supply module to generate power required for the operation of the electronic device 1000.

At least one of the components of the electronic device 1000 described above may be included in the display device 10 according to embodiments described above. Additionally, some of the individual modules functionally included within a module may be included within the display device, while others may be provided separately from the display device. For example, the display device 10 includes a display module 1100, and the processor 1200, memory 1300, and power module 1400 may be provided in the form of other devices within the electronic device 1000 other than the display device 10.

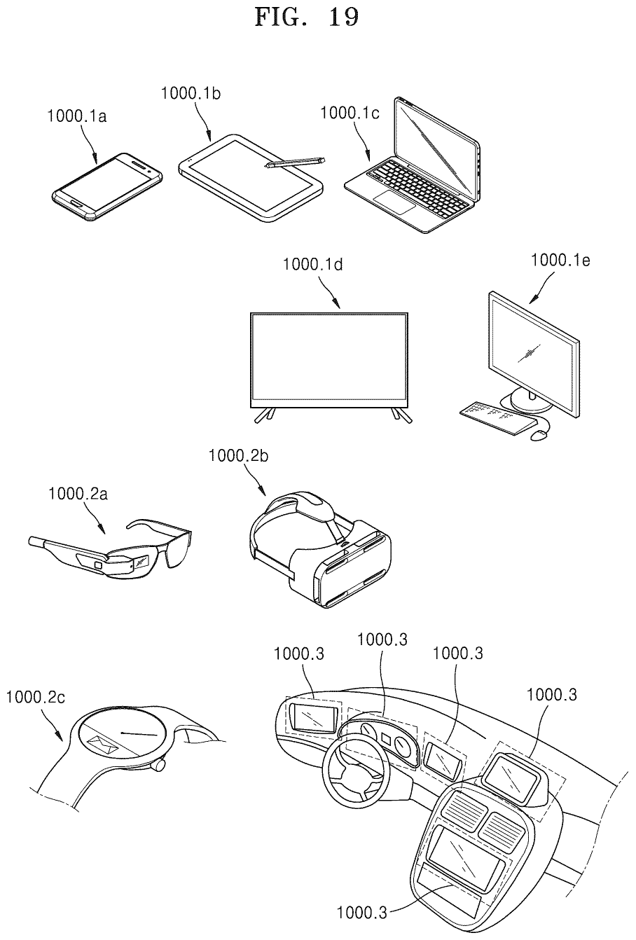

FIG. 19 is a schematic diagram of an electronic device according to various embodiments.

Referring to FIG. 19, various electronic devices to which a display device 10 according to embodiments is applied may include not only image display electronic devices such as a smartphone 1000.1a, a tablet PC 1000.1b, a laptop 1000.1c, a TV 1000.1d, a desk monitor 1000.1e, but also wearable electronic devices including display modules such as smart glasses 1000.2a, a head-mounted display 1000.2b, a smart watch 1000.2c, and the like, and vehicle electronic devices 1000.3 including display modules such as a CID (Center Information Display) and a room mirror display arranged on a dashboard, center fascia, or a car instrument panel.

According to an embodiment of the present disclosure, an uneven portion is arranged in an insulating layer between wirings respectively connected to a source region, a drain region, and a gate electrode, thereby increasing surface resistance between wirings, alleviating and/or preventing current leakage, and implementing a display device with improved reliability, a method of manufacturing the same, and an electronic device including the same.

However, the effects obtainable through the present disclosure are not limited to the effects described above, and other technical effects not mentioned will be clearly understood by those skilled in the art from the description of the present disclosure described above.

Each of the embodiments described above may be implemented independently, but it goes without saying that the structure of each embodiment may be applied in combination to other embodiments.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although the present disclosure has been described with reference to the embodiments shown in the drawings, these are merely examples, and those skilled in the art will understand that various modifications and other equivalent embodiments are possible therefrom. Therefore, the scope of the present disclosure should be determined by the appended patent claims.

The specific implementations described in the embodiments are intended to be illustrative only and do not limit the scope of the embodiments in any way. Additionally, if there is no specific mention such as “essential” or “important,” it may not be a component absolutely necessary for the application of the present disclosure.

The use of the term “above” and similar referential terms in the specification of embodiments (especially in the claims) may refer to both the singular and the plural. In addition, when a range is described in an embodiment, the present disclosure includes an individual value within the range (unless otherwise stated), which is equivalent to specifying each individual value that constitutes the range in the detailed description. Finally, regarding steps constituting a method according to an embodiment, unless there is an explicit description of the order or contrary description, the steps may be performed in any suitable order. The embodiments are not necessarily limited to the order in which the above steps are described. Any use of examples or example terms in the embodiments is merely intended to elaborate aspects of the embodiments and is not intended to limit the scope of the embodiments, unless otherwise defined by the claims. Furthermore, those skilled in the art will appreciate that various modifications, combinations and variations may be made according to design conditions and factors within the scope of the appended claims or their equivalents.

What is claimed is:

1. A display device comprising:
a substrate;
a thin-film transistor on the substrate;
an interlayer insulating film on the thin-film transistor; and
signal wirings on the interlayer insulating film and electrically connected to the thin-film transistor, wherein
a surface of the interlayer insulating film has an uneven portion between the signal wirings.

2. The display device of claim 1, wherein
the thin-film transistor includes a semiconductor layer, a gate insulating film, and a gate electrode,
the semiconductor layer includes a channel region, a source region, and a drain region,
the source region and the drain region are respectively positioned on opposite sides of the channel region, and
the gate electrode overlaps the channel region, and
the gate insulating film is between the gate electrode and the channel region.

3. The display device of claim 2, wherein
the signal wirings comprise a first signal wiring, a second signal wiring, and a third signal wiring,
the first signal wiring is configured to apply a gate signal to the gate electrode,
the second signal wiring is electrically connected to the source region,
the third signal wiring is electrically connected to the drain region, and
the uneven portion is between the first signal wiring, the second signal wiring, and the third signal wiring.

4. The display device of claim 1, wherein the uneven portion includes at least one concave portion.

5. The display device of claim 4, wherein a depth of the at least one concave portion is 500 Å or more and 1000 Å or less.

6. The display device of claim 4, wherein
the at least one concave portion includes two or more concave portions having different depths from each other, different widths from each other, or both different depths from each other and different widths from each other.

7. The display device of claim 1, wherein the interlayer insulating film further includes an additional insulating film covering the uneven portion.

8. The display device of claim 7, wherein a thickness of the additional insulating film is 500 Å or more and 1000 Å or less.

9. The display device of claim 7, wherein a permittivity of the additional insulating film is 4 or less.

10. A method of manufacturing a display device, comprising:
forming a thin-film transistor on a substrate by sequentially forming a semiconductor layer, a gate insulating film, and a gate electrode on the substrate;
forming an interlayer insulating film on the thin-film transistor;
forming an uneven portion on a surface of the interlayer insulating film; and
forming signal wirings electrically connected to the thin-film transistor, the signal wirings being formed on the interlayer insulating film.

11. The method of claim 10, wherein the forming the uneven portion on the surface of the interlayer insulating film comprises:
forming a photoresist layer by coating a photoresist material on the interlayer insulating film;
forming a photoresist pattern on the photoresist layer using a half-tone mask; and
patterning the interlayer insulating film using the photoresist pattern as a mask.

12. The method of claim 11, wherein the forming the photoresist pattern comprises performing an exposure process and a development process on the photoresist material.

13. The method of claim 10, wherein the uneven portion is between the signal wirings.

14. The method of claim 10, further comprising:
between the forming the thin-film transistor and the forming the interlayer insulating film, forming a source region in the semiconductor layer and a drain region in the semiconductor layer by doping an impurity into the semiconductor layer using the gate electrode as a mask.

15. The method of claim 14, wherein
the signal wirings include a first signal wiring, a second signal wiring, and a third signal wiring,
the first signal wiring is configured to apply a gate signal to the gate electrode,
the second signal wiring is electrically connected to the source region, and
the third signal wiring electrically connected to the drain region, and
the uneven portion is on the surface of the interlayer insulating film between the first signal wiring, the second signal wiring, and the third signal wiring.

16. The method of claim 10, further comprising:
forming an additional insulating film on the interlayer insulating film between the signal wirings.

17. The method of claim 16, wherein the forming the additional insulating film comprises:
coating a photoresist material on the signal wirings;
depositing an additional insulating material on the photoresist material and on the interlayer insulating film; and
removing the photoresist material.

18. The method of claim 10, wherein the uneven portion includes at least one concave portion.

19. The method of claim 18, wherein a depth of the at least one concave portion is 500 Å or more and 1000 Å or less.

20. An electronic device comprising:
a display device, wherein
the display device comprises a substrate, a thin-film transistor on the substrate, an interlayer insulating film on the thin-film transistor, and signal wirings on the interlayer insulating film,
the signal wirings are electrically connected to the thin-film transistor, and
a surface of the interlayer insulating film includes an uneven portion between the signal wirings.
